(19) United States
(12) Patent Application Publication
(10) Pub. No.: US 2008/0113278 A1
(43) Pub. Date: May 15, 2008

(54) PHOTOMASK LAYOUT FOR A SEMICONDUCTOR DEVICE AND METHOD OF FORMING A PHOTOMASK PATTERN USING THE PHOTOMASK LAYOUT

(75) Inventors: Sang-Hee Lee, Seoul (KR); Ho-June Lee, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/872,879

(22) Filed: Oct. 16, 2007

(30) Foreign Application Priority Data
Oct. 24, 2006 (KR) 2006-103253

(51) Int. Cl. G03F 1/00

(52) U.S. Cl. 430/5

(57) ABSTRACT

In a photomask layout for forming a photomask pattern, the photomask layout includes a first mother pattern corresponding to a principal pattern of the photomask pattern, a second mother pattern corresponding to a supplementary pattern of the photomask pattern and a guide pattern that controls the shot size of illumination light for transcribing the first and the second mother patterns, respectively. The principal pattern is transcribed onto a semiconductor substrate, and the supplementary pattern is positioned between the principal patterns and prevents transcription failures of the principal pattern without transcription onto the semiconductor substrate. The shot size of the light is reduced on a basis of the guide pattern to thereby accurately form a minute pattern of the semiconductor device.

### CROSS-REFERENCE TO RELATED APPLICATIONS

This application claims priority under 35 U.S.C. § 119 to Korean Patent Application No. 2006-103253, filed on Oct. 24, 2006 in the Korean Intellectual Property Office (KIPO), the contents of which are herein incorporated by reference in their entirety.

### FIELD OF THE INVENTION

The present invention relates generally to semiconductor devices and, more particularly, semiconductor device manufacturing.

### BACKGROUND OF THE INVENTION

As semiconductor devices are highly integrated, fine patterns having minute widths and spaces among the patterns, and fine photomask patterns that are transcribed into the fine patterns may need to be formed on a substrate. Recently, a critical dimension (CD) of a semiconductor device has been reduced to be smaller than a wavelength of the illumination light in an exposure system, so that there are some difficulties in transcribing the photomask pattern onto the semiconductor device with the same shape and CD of the photomask pattern due to an optical proximity effect.

In general, a conventional photomask pattern has been formed by the following processing steps. At first, a light-shielding layer, a hard mask layer and a photoresist film are sequentially stacked on a transparent substrate, and an exposure process is performed on the photoresist film using a photomask layout. The photomask layout includes a mother pattern that is eventually to be transcribed onto a semiconductor substrate. The exposed photoresist film is developed through a developing process to thereby form a photoresist pattern corresponding to the photomask layout. Then, the hard mask layer is patterned by an etching process using the photoresist pattern as an etching mask, to thereby form a photomask pattern on the transparent substrate in accordance with the photomask layout.

In a conventional patterning process for a semiconductor device, lifting failures are usually generated at an alteration point at which the size or pitch of a pattern is changed due to an optical proximity effect or a coma effect during an exposure process. So as to minimize the lifting failures of the pattern, an off-axis exposure process and a phase shift exposure process using a phase shift mask has been performed instead of the normal exposure process. However, empirical results show that the off-axis exposure process and a phase shift exposure process may be insufficient to minimize the lifting failures of the pattern. The lifting failures of the pattern may significantly reduce an allowable error range of the patterning process, so that the photomask pattern may be difficult to accurately transcribe onto the semiconductor substrate. Particularly, the recent trend of decreasing CDs in semiconductor devices accelerates the reduction of the allowable error range of the patterning process, and thus device patterns for a semiconductor device may be much more difficult to accurately form on the semiconductor substrate in accordance with the photomask pattern.

So as to solve the above problems, a method has been proposed in which a scattering bar is arranged around the photomask pattern. The scattering bar is a supplemental pattern that is arranged around the photomask pattern and is not transcribed onto the semiconductor substrate to thereby improve the transcription accuracy of the photomask pattern. The scattering bar may be positioned into a cross shape that encloses an edge portion of the photomask pattern or may be positioned in a space between the neighboring photomask patterns as a parallel shape that is parallel with the neighboring mask patterns.

The recent trend of decreasing CDs in semiconductor devices may require photomask patterns to have reduced sizes and small spaces among neighboring photomask patterns. Therefore, there have been difficulties in arranging scattering bars in the spaces among the neighboring photomask patterns. Further, the conventional photomask pattern may be difficult to form to a width smaller than about 100 nm due to resolution limitations of light sources of the exposure system, such as an electron beam and a laser, and a conventional scattering bar usually has a size of about 105 nm to about 110 nm between conventional neighboring photomask patterns. Accordingly, the conventional scattering bar typically is not used as the supplementary pattern for the photomask pattern of which the width is required to be smaller than about 100 nm.

The above size limitation of the scattering bar is caused by some characteristics of a light source of the exposure system. When an electron beam is used as illumination light in the exposure process for the photomask pattern, a reciprocal repulsive force between the electron beams causes interference at an edge portion of a shot size of a photomask layer due to an aberration effect, and thus the edge portion of the photomask pattern becomes round. That is, the photomask layout is not accurately transcribed onto the transparent substrate, and the photomask pattern and the scattering bar may have distorted shapes as a result. The aberration effect is usually proportional to the shot size and an electrical current for generating the electron beam.

FIG. 1 is a view illustrating a conventional photomask layout, and FIG. 2 is a scanning electron microscope (SEM) picture showing a photomask pattern that is patterned in accordance with the photomask layout in FIG. 1.

Referring to FIGS. 1 and 2, the conventional photomask layout includes a first mother pattern 51 for forming a principal pattern 51a of a photomask pattern and a second mother pattern 52 for forming a supplementary pattern 52a of the photomask pattern. The principal pattern 51a of the photomask pattern is transcribed onto a semiconductor device. In contrast, the supplementary pattern 52a of the photomask pattern is not transcribed onto the semiconductor substrate, but rather may merely prevent transcription failures of the principal pattern 51a due to an optical proximity effect. The second mother pattern 52 is transcribed into the transparent substrate to thereby form a plurality of scattering bars 52a around a lower portion of the principal pattern 51a, in order that a shape alteration portion of the principal pattern 51a may be accurately transcribed onto the semiconductor substrate without any pattern distortion, such as a shape modification or a pattern break. However, the width and pitch of the scattering bar 52a has been significantly reduced according to a recent requirement of fine patterns in semiconductor devices, and thus there is a problem in that the second mother pattern 52 of the photomask layout is not accurately transcribed onto the transparent substrate as the scattering bar 52a.

As shown in FIG. 2, when the photomask layout in FIG. 1 is transcribed onto the transparent substrate as the photomask pattern, the principal pattern 51a is accurately formed on the transparent substrate. In contrast, the supplementary pattern 52a is not accurately transcribed in accordance with the second mother pattern 52 of the photomask layout, and the shape of the pattern is significantly distorted because of the reciprocal repulsive force between the electron beams.

FIG. 3 is a graph showing a relationship between the pattern distortion and shot size of the electron beam. In FIG. 3, a horizontal axis represents the shot size of the electron beam, and a vertical axis represents the pattern distortion. The pattern distortion indicates a degree of deviation between the photomask layout and the photomask pattern that is transcribed from the photomask layout.

As shown in FIG. 3, the smaller the shot size is, the less the pattern distortion is. That is, when the electron beam is radiated into a small shot size, the reciprocal repulsive force between neighboring electron beams is small, and thus much less aberration is generated around the photomask pattern. The above results in FIG. 3 indicate that reduction of the shot size may sufficiently prevent the pattern distortion of the photomask pattern in case that the scattering bar is required to be positioned at a limited space of the photomask pattern.

However, the shot size is one of the recipes of the exposure system, and an operator of the exposure system usually determines the shot size in advance before the exposure process. Therefore, the shot size cannot be changed during the exposure process. Particularly, the photomask pattern for a semiconductor device is formed in nanometer scale, and thus the operator of the exposure system cannot verify the shot size of the illumination light at each portion in which the scattering bar is located. As a result, it may be impossible for the operator to change the shot size during the exposure process.

### SUMMARY OF THE INVENTION

Accordingly, the present invention provides a photomask layout for efficiently forming a minute scattering bar on a transparent substrate.

The present invention also provides a method of forming a photomask pattern using the above photomask layout.

According to an embodiment of the present invention, there is provided a photomask layout including a first mother pattern, a second mother pattern and a guide pattern. The first mother pattern corresponds to a principal pattern of the photomask pattern, and the principal pattern is transcribed onto a semiconductor substrate. The second mother pattern corresponds to a supplementary pattern of the photomask pattern, and the supplementary pattern is positioned between the principal patterns and may prevent transcription failures of the principal pattern without transcription onto the semiconductor substrate. The guide pattern controls a shot size of illumination light for transcribing the first and the second mother patterns, respectively.

In some embodiments, a plurality of the second mother patterns are positioned between the first mother patterns along a longitudinal direction of the first mother pattern, the second mother pattern being spaced apart from the first mother pattern and an adjacent second mother pattern by a first distance. The guide pattern is spaced apart from a boundary of the second mother pattern by a second distance and is aligned with the second mother pattern.

For example, the second mother pattern may have a width of about 100 nm to about 120 nm, and the first distance is in a range of about 200 nm to about 500 nm. The second distance is in a range of about 20 nm to about 30 nm, and the guide pattern has a width smaller than a wavelength of illumination light for transcribing the first and second mother patterns, so that the guide pattern is not transcribed during an exposure process for forming the photomask pattern.

In some embodiments, a plurality of the second mother patterns are positioned correspondingly to each of the corner portions of the first mother pattern, and the guide pattern is spaced apart from a boundary of the second mother pattern by a second distance and is aligned with the second mother pattern.

According to other embodiments of the present invention, there is provided a method of forming a photomask pattern using the above photomask layout.

A photomask layout for a photomask pattern includes a first mother pattern corresponding to a principal pattern of a photomask pattern, a second mother pattern corresponding to a supplementary pattern of the photomask pattern, and a guide pattern that controls the shot size of the illumination light for transcribing the first and the second mother patterns, respectively. A photomask structure is provided into a processing chamber of an exposure system. The photomask structure is formed into the photomask pattern by an exposure process in the exposure system. The layout is inputted into the exposure system. The photomask structure is exposed to the illumination light of the exposure system in accordance with the first and second mother patterns of the layout. The principal pattern and the supplementary pattern are formed in the photomask structure in accordance with the first and second mother patterns of the layout to thereby form the photomask pattern. The principal pattern is transcribed onto a semiconductor substrate and the supplementary pattern is positioned between the principal patterns and may prevent transcription failures of the principal pattern without transcription onto the semiconductor substrate.

In some embodiments, the step of forming the layout includes positioning the guide pattern along a boundary of the second mother pattern, and the guide pattern is spaced apart from the second mother pattern within an allowable detection error range of the exposure system with respect to the second mother pattern. The formation of the layout may be performed by a computer graphic tool, and the layout is input into the exposure system as a computer image file, of which the extension name is that of a graphic design system (GDS) file type. The step of inputting the layout into the exposure system is performed simultaneously with a setting of recipes for the exposure process.

In some embodiments, the second mother pattern is spaced apart from the guide pattern by a distance of about 20 nm to about 30 nm. The exposure system detects the first and second mother patterns of the layout and irradiates the illumination light onto the photomask structure in accordance with the first and second mother patterns of the layout. The illumination light includes an electron beam.

As an example embodiment, the step of exposing the photomask structure includes detecting a non-pattern area of the layout in which the first mother pattern, the second mother pattern and the guide pattern are not positioned, performing a first exposure process on the photomask structure by repeatedly irradiating the illumination light to the photomask structure corresponding to the non-pattern area of the layout at a normal shot size, so that the photomask structure is exposed to the illumination light by every normal segment, and performing a second exposure process on the photomask structure by repeatedly irradiating the illumination light to the photomask structure corresponding to the non-pattern area of the layout near the guide pattern at a reduced shot size smaller than the normal size, so that the photomask structure is exposed to the illumination light by every reduced segment smaller than the normal segment in case that the guide pattern is detected.

For example, the layout may include a computer image file, such as a GDS file, and the step of detecting the non-pattern area of the layout includes scanning the layout by pixel. The normal segment includes a square having a length of about 200 nm to about 500 nm, and the reduced segment includes a square having a length of about 20 nm to about 30 nm.

In some embodiments, the photomask structure includes a transparent substrate through which the illumination light passes, a light-shielding layer that is formed on the transparent substrate for selectively shielding the illumination light, a hard mask layer that is formed on the light-shielding layer and has an etching selectivity with respect to the light-shielding layer, and a photoresist film that is formed on the hard mask layer and of which the molecular structure is changed by the illumination light irradiated thereto.

The step of forming the principal pattern and the supplementary pattern includes transforming the photoresist film into a photoresist pattern in accordance with the first mother pattern and the second mother pattern of the layout by a photolithography process, forming a hard mask pattern on the light-shielding layer by a first etching process using the photoresist pattern as an etching mask, and forming a light-shielding pattern on the transparent substrate by a second etching process using the hard mask pattern as an etching mask, the light-shielding pattern including the principal pattern corresponding to the first mother pattern of the layout and the supplementary pattern corresponding to the second mother pattern of the layout. For example, the first etching process may include a dry etching process using a gas comprising halogen elements as an etching gas, and the second etching process includes a plasma etching process using chlorine (Cl₂) gas and oxygen (O₂) gas as an etching gas.

In some embodiments, the transparent substrate includes a glass substrate, a fused silica substrate or a quartz substrate. The light-shielding layer includes a full light-shielding layer comprising any one material selected from the group consisting of aluminum (Al), tungsten (W) and chromium (Cr), or a half light-shielding layer comprising any one material selected from the group consisting of molybdenum (Mo), molybdenum silicon nitride (MoSiN) and molybdenum silicon oxynitride (MoSiON).

According to some embodiments of the present invention, an electron beam may be irradiated onto a minute region of a transparent substrate at a reduced shot size without any manual change between a normal region and the minute region of the transparent substrate, so that a photomask pattern is formed on the transparent substrate accurately in accordance with a layout despite a small line width and pitch thereof. Particularly, a scattering bar, which is a supplementary pattern for accurately transcribing a principal pattern of the photomask pattern into a minute device pattern without any pattern distortion, may be formed in the photomask pattern, to thereby sufficiently improve the resolution of the device pattern without any modifications to the exposure system.

### BRIEF DESCRIPTION OF THE DRAWINGS

The above and other features and advantages of the present invention will become readily apparent by reference to the following detailed description when considering in conjunction with the accompanying drawings, in which:

FIG. 1 is a view illustrating a conventional photomask layout;

FIG. 2 is a scanning electron microscope (SEM) picture showing a photomask pattern that is patterned in accordance with the photomask layout in FIG. 1;

FIG. 3 is a graph showing a relationship between the pattern distortion and shot size of an electron beam;

FIG. 4 is a view illustrating a photomask layout in accordance with some embodiments of the present invention;

FIG. 5 is a flow chart showing a method of forming a photomask pattern using the photomask layout shown in FIG. 4;

FIG. 6 is a flow chart showing steps of exposing the photomask structure to the illumination light in the exposure system in accordance with some embodiments of the present invention;

FIG. 7 is a flow chart showing a method of forming a photomask pattern in accordance with some embodiments of the present invention; and

FIG. 8 is an SEM picture showing the photomask pattern that is formed by the method of forming the photomask pattern shown in FIG. 4.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 4 is a view illustrating a photomask layout in accordance with some embodiments of the present invention.

Referring to FIG. 4, the illustrated photomask layout 500 includes a first mother pattern 510 that is to be transcribed into a principal pattern of a photomask pattern on a transparent substrate, a second mother pattern 520 that is to be transcribed into a supplemental pattern of the photomask pattern on the transparent substrate, and a guide pattern 530 for controlling shot sizes of the first and second mother patterns 510 and 520. The principal pattern is to be transcribed into a device pattern on a semiconductor substrate, and the supplemental pattern is located in a space between the principal patterns on the transparent substrate and is not to be transcribed on the semiconductor substrate. The supplemental pattern may merely prevent transcription failures of the principal pattern due to the optical proximity effect.

Because the first mother pattern 510 is transcribed into the principal pattern of the photomask pattern, a photoresist pattern is formed on the semiconductor substrate in accordance with the principal pattern by a photolithography process using the photomask pattern.

The second mother pattern 520 is transcribed into the supplemental pattern of the photomask pattern on the transparent substrate. The supplemental pattern is positioned in the space between the principal patterns, and is not transcribed into the device pattern on the semiconductor substrate. The supplemental pattern may merely prevent transcription failures of the principal pattern due to the optical proximity effect. When the size of the device pattern is smaller than the resolution of the exposure system, the principal pattern is not accurately transcribed into the device pattern because of the optical proximity effect to thereby generate the pattern distortion of the principal pattern. Accordingly, marginal dimensions of the device patterns are different from one another according to positions of each device pattern on the semiconductor substrate. The transcription failures of the principal pattern are much more severely generated particularly when the principal pattern is isolated from other patterns on the transparent substrate or the variation of the shape of the principal pattern is great. The supplementary patterns are positioned in the space of the transparent substrate between the principal patterns and minimize the isolation of the principal pattern or the variation of the shape of the principal pattern.

While the above discloses that the supplementary patterns are positioned between the principal patterns, the supplementary pattern may be located at any position where the electron beam is interrupted due to the great variation of the shape of the principal pattern. That is, the location of the supplementary pattern is not limited to within the space of the transparent substrate between the principal patterns. For example, the supplementary pattern may be located around a corner portion of the principal pattern, so that the transcription failures of the principal pattern are sufficiently prevented at the corner portion thereof. That is, the corner portion of the principal pattern is accurately transcribed into the device pattern without any pattern distortion on the semiconductor substrate. Accordingly, the supplementary pattern is located at a position of the transparent substrate at which the shape of the principal pattern is greatly varied, and reduces the effect of the great shape variation of the principal pattern in the exposure process for forming the device pattern.

In some embodiments, the second mother pattern 520 has a width smaller than the resolution of illumination light for a photolithography process with respect to the semiconductor substrate, and thus the supplementary pattern also has a width smaller than the resolution of the illumination light. As a result, the supplementary pattern is not transcribed onto the semiconductor substrate during the photolithography process using the photomask pattern.

The resolution of an exposure system is determined by the Rayleigh equation as expressed in the following Equation (1).

$$R = k \frac{λ}{N A} \qquad ( 1 )$$

In Equation (1), the letter ‘k’ indicates a constant, and the Greek letter ‘λ’ indicates a wavelength of the illumination light of an exposure system. The letters ‘NA’ indicate a numeral aperture of a lens of the exposure system. For example, when the exposure system includes a lens unit of which a numerical aperture NA is about 0.65, and uses the illumination light having a wavelength λ of about 0.194 with a constant k of about 0.5, the resolution of the exposure system is about 149 nm. When a photolithography process is performed with respect to the semiconductor substrate using the photomask pattern in the above exposure system, the pattern distortion of the principal pattern is sufficiently prevented in case that the width of the supplementary pattern is smaller than about 149 nm. Accordingly, the second mother pattern 520 of the photomask layout 500 needs to have a width smaller than about 149 nm. For example, the second mother pattern 520 may have a width of about 100 nm to about 120 nm, and is separated from the first mother pattern 510 by a distance of about 200 nm to about 500 nm. In addition, when a plurality of the second mother patterns 520 is formed in the photomask layout 500, each of the second mother patterns 520 may be separated from each other by a distance of about 200 nm to about 500 nm.

In some embodiments, the guide pattern 530 is positioned adjacent to the second mother pattern 520 along a longitudinal sidewall of the second mother pattern 520, and provides a base line for controlling the shot size of illumination light around the second mother pattern 520. For example, when an electron beam is irradiated onto the photomask layout and the first and the second mother patterns 510 and 520 are transcribed onto the transparent substrate, the second mother pattern 520 may be accurately transcribed onto the transparent substrate without any pattern distortion despite a minute space between the first and the second mother patterns 510 and 520 or between the second mother patterns 520, because the shot size of the electron beam is readjusted near the second mother pattern 520 based on the guide pattern 530. For example, the shot size of the electron beam may be adjusted into a square of about 20 nm to about 30 nm around the second mother pattern 520. Accordingly, the shot size of the electron beam may be sufficiently scaled down, and thus an electrical repulsive force may be sufficiently minimized between neighboring electron beams when the photomask pattern is formed on the transparent substrate using the photomask layout 500 including the guide pattern 530. Therefore, the pattern distortion caused by the electrical repulsive force may be sufficiently prevented during the irradiation of the electron beam, to thereby much more accurately form the supplementary pattern on the transparent substrate. For example, the supplementary pattern may be formed into a width of about 60 nm to about 100 nm. In some embodiments, the guide pattern 530 may be separated from the second mother pattern 520 by a distance of about 20 nm to about 30 nm.

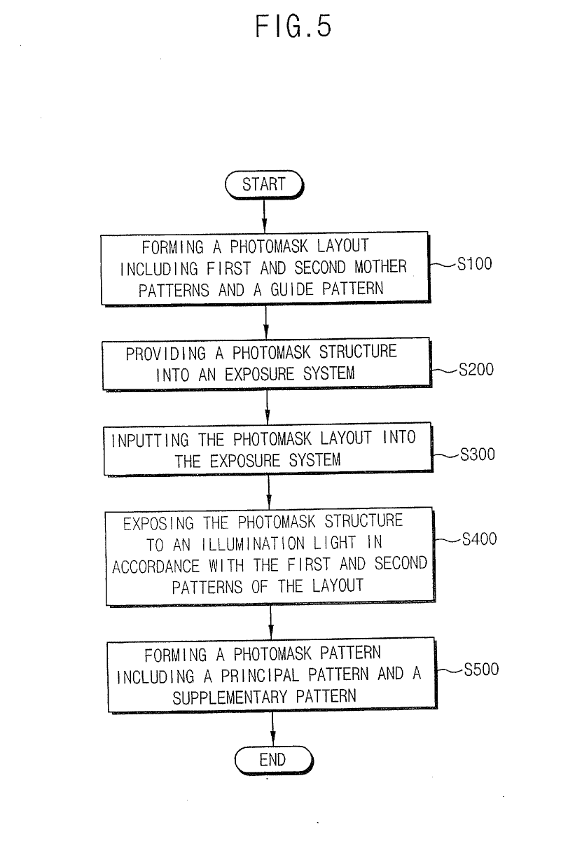

FIG. 5 is a flow chart showing a method of forming a photomask pattern using the photomask layout shown in FIG. 4.

Referring to FIGS. 4 and 5, the photomask layout 500 that is transcribed into the photomask pattern and includes a guide pattern is firstly prepared (step S100). In some embodiments, the photomask layout for forming the photomask pattern includes a first mother pattern 510 that is to be transcribed into a principal pattern of a photomask pattern on a transparent substrate, a second mother pattern 520 that is to be transcribed into a supplemental pattern of the photomask pattern on the transparent substrate, and a guide pattern 530 for controlling shot sizes of the first and second mother patterns 510 and 520. The principal pattern is to be transcribed into a device pattern on a semiconductor substrate, and the supplemental pattern is located in a space between the principal patterns on the transparent substrate and is not to be transcribed on the semiconductor substrate. The supplemental pattern may merely prevent transcription failures of the principal pattern due to the optical proximity effect. The photomask layout 500 is the same as the layout shown in FIG. 4, so any further detailed description on the photomask layer will be omitted.

In some embodiments, the photomask layout 500 may be generated as digital material, such as a computer file, by a design tool for a photomask layout. For example, the layout may include an image file, for example a graphic design system (GDS) file type, so that the GDS image file is provided into the exposure system. However, various types of image files may be used in accordance with embodiments of the present invention, without limitation. Further, the guide pattern is positioned adjacent to the second mother pattern along a longitudinal direction of the second mother pattern, and is spaced apart from the second mother pattern within an allowable detection error range of the second mother pattern. For example, the guide pattern may be separated from the second mother pattern by a distance of about 2 nm to about 3 nm. The photomask layout may be generated as the GDS image file by a computer graphic tool, and the GDS image file of the photomask layout is inputted into the exposure system simultaneously with other recipes of the exposure process.

A photomask structure for forming a photomask pattern is prepared (step S200). In some embodiments, the photomask structure includes a transparent substrate through which most of illumination light passes, a light-shielding layer on the transparent substrate for selectively shielding the illumination light, a hard mask layer that is formed on the light-shielding layer and has an etching selectivity with respect to the light-shielding layer, and a photoresist film that is formed on the hard mask layer and of which the molecular structure is changed by the illumination light irradiated thereto. The photoresist film is formed into a photoresist pattern by an exposure process, and the hard mask layer is formed into a hard mask pattern by an etching process using the photoresist pattern as an etching mask. The light-shielding layer is then formed into a light-shielding pattern by an etching process using the hard mask pattern as an etching mask. As a result, the transparent substrate is partially exposed through the light-shielding pattern thereon.

The transparent substrate may include, for example, glass, fused silica or quartz, and the light-shielding layer may include, for example, a fully shielding layer or a half shielding layer. In some embodiments, the fully shielding layer exemplarily comprises aluminum (Al), tungsten (W), or chromium (Cr), and the half-shielding layer exemplarily comprises molybdenum silicon nitride (MoSiN) or molybdenum silicon oxynitride (MoSiON). The hard mask layer may comprise conductive materials and may have an etching selectivity higher than about 3:1 with respect to the light-shielding layer. Further, the hard mask layer may comprise some materials insoluble to a cleaning solution, which is a mixture of an acid, an alkali, water (H₂O) and hydrogen peroxide (H₂O₂). In addition, the hard mask layer may comprise such a material that the hard mask pattern may be removed from the light-shielding pattern without any damage to the transparent substrate. Furthermore, the hard mask layer may also have an etching selectivity with respect to an organic stripper for removing the photoresist pattern from the hard mask pattern. In the present example embodiment, the hard mask layer may comprise one of molybdenum (Mo), molybdenum silicon (MoSi) and molybdenum silicon oxynitride (MoSiON), or one of hafnium (Hf) and a hafnium compound. When the photoresist film is selectively exposed by the illumination light, the molecular structure of the photoresist film is changed due to the illumination light, and thus the solubility of an exposed portion of the photoresist film is different from that of an unexposed portion of the photoresist film with respect to a developing solution. As a result, the photoresist layer is formed into the photoresist pattern by the solubility difference between the exposed and the unexposed portions thereof. The photoresist layer may be classified into a positive type and a negative type in accordance with a molecular reaction to the illumination light irradiated thereto.

Then, the photomask structure including the transparent substrate, the light-shielding layer, the photomask layer and the photoresist film is provided into an exposure chamber of the exposure system, and the photomask layout is input into the exposure system (step S300). In some embodiments, the exposure system includes a closed chamber (not shown), a light source (not shown) located over the closed chamber, and a layout processing unit (not shown) connected to the light source. For example, the photomask structure may be positioned on a support in the closed chamber in such a manner that the photoresist film of the photomask structure faces the light source. In the present embodiment, the light source may include an electron beam.

Because the photomask layout is provided into the exposure system as an image file that may be controllable by a computer system, such as a GDS file, the input of the photomask layout may be performed merely by an operation for loading the GDS file into a central processing unit (CPU) of a computer system of the exposure system. In some embodiments, initial recipes of the exposure system may include the image file of the photomask layout.

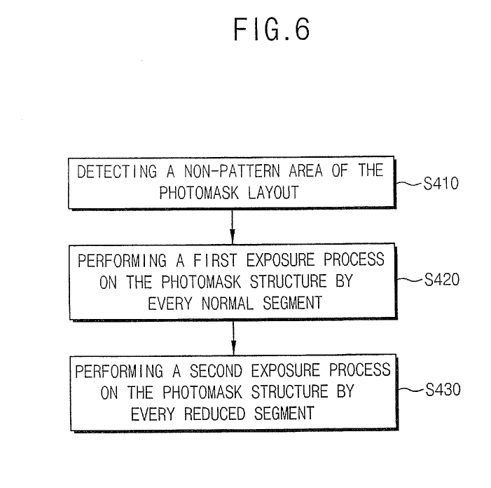

The photomask structure is then exposed to the illumination light in the exposure system in accordance with first and second guide patterns of the photomask layout (step S400). FIG. 6 is a flow chart showing steps of exposing the photomask structure to the illumination light in the exposure system in accordance with some embodiments of the present invention.

Referring to FIG. 6, the exposure system scans the GDS image file of the photomask layout and detects a pattern area and a non-pattern area from the photomask layout (step S410). For example, the detection of the non-pattern area of the layout may include a pixel-by-pixel scan to the GDS image file of the layout.

Then, the illumination light is repeatedly irradiated onto the photomask structure at a normal shot size of the exposure system in accordance with the detected non-pattern area of the layout, so that a first exposure process is performed on the photomask structure by every normal segment that corresponds to the normal shot size (step S420). Particularly, the non-pattern area of the layout is detected according to shot size, which is one of the recipes of the exposure system, and an electron beam is irradiated onto the photomask structure, which corresponds to the non-pattern area of the layout, at the normal shot size. That is, the photomask structure corresponding to the non-pattern area of the layout is separated into a plurality of the normal segments in accordance with the normal shot size, and the electron beam is irradiated onto each of the normal segments of the photomask structure on a basis of boundary lines of the mother patterns of the layout 500. Accordingly, the photoresist film in each normal segment is exposed to the electron beam at the normal shot size. After completing the irradiation of the electron beam to the photomask structure corresponding to the non-pattern area of the layout, the photoresist film corresponding to the pattern area of the layout is then exposed to the electron beam. For example, the normal segment of the photomask structure may include a triangular or a rectangular shape. In some embodiments, the normal segment of the photomask structure includes a square having a length of about 200 nm to about 500 nm.

When the guide pattern 530 of the layout is detected during the irradiation of the electron beam, the normal shot size of the electron beam is decreased to a reduced shot size smaller than the normal shot size, and the electron beam is repeatedly irradiated onto the photomask structure at the reduced shot size. Accordingly, a second exposure process is performed on the photomask structure by every reduced segment corresponding to the reduced shot size of the electron beam (step S430).

Particularly, when the guide pattern 530 of the layout 500 is detected by the exposure system, a control unit of the exposure system decreases the shot size of the electron beam into the reduced shot size. Information on the reduced shot size of the electron beam is stored in the recipes of the exposure system. Therefore, the electron beam is much more minutely irradiated onto the photomask structure by every reduced segment. For example, the reduced segment may include a square having a length of about 20 nm to about 30 nm.

That is, when the electron beam passes through a minute region R of the layout 500, the photomask structure is exposed to the electron beam by every reduced segment. The minute region R of the layout 500 includes portions of the layout 500 between the first and second mother patterns 510 and 520 and between the neighboring second mother patterns 520. Accordingly, the electron beams passing through the first and second mother patterns 510 and 520 have no effect on each other despite the small size and pitch of the second mother pattern 520, so that the first and second mother patterns 510 and 520 may be accurately transcribed into the photomask structure without any pattern distortion. As shown in FIG. 1, the smaller the shot size of the electron beam is, the less the pattern distortion is, and thus the irradiation of the electron beam to the reduced segment of the photomask structure may improve the accuracy of the transcription to the photomask structure. Accordingly, the scattering bar of the photomask pattern may be accurately formed on the transparent substrate without pattern distortion despite the small size thereof.

When a gap distance between neighboring patterns is smaller than the reduced shot size of the electron beam, the electron beam cannot pass through the gap distance of the layout 500, and the exposure system detects the neighboring patterns as one pattern. For example, the layout 500 may be designed into such a structure that the gap distance G between the second mother pattern 520 and the guide pattern 530 is sufficiently smaller than the reduced shot size of the electron beam, so that the exposure system detects as if the second mother pattern 520 and the guide pattern 530 are the same pattern. That is, the second mother pattern 520 and the guide pattern 530 of the layout may be spaced apart by a distance within an allowable detection error range of the control unit of the exposure system. For example, the second mother pattern 520 and the guide pattern 530 may be spaced apart by a distance of about 20 nm to about 30 nm.

When the photomask structure corresponding to the minute region R of the layout 500 is sufficiently exposed to the electron beam by every reduced segment, the control unit of the exposure system changes the reduced shot size into the normal shot size. Therefore, the photomask structure is exposed to the electron beam by every normal segment. Irradiation of the electron beam by every reduced segment may decrease the efficiency of the exposure process, so that the shot size of the electron beam is controlled to be reduced only when the electron beam passes the minute region R of the layout 500 so as to minimize the efficiency decrease of the exposure process to the photomask structure.

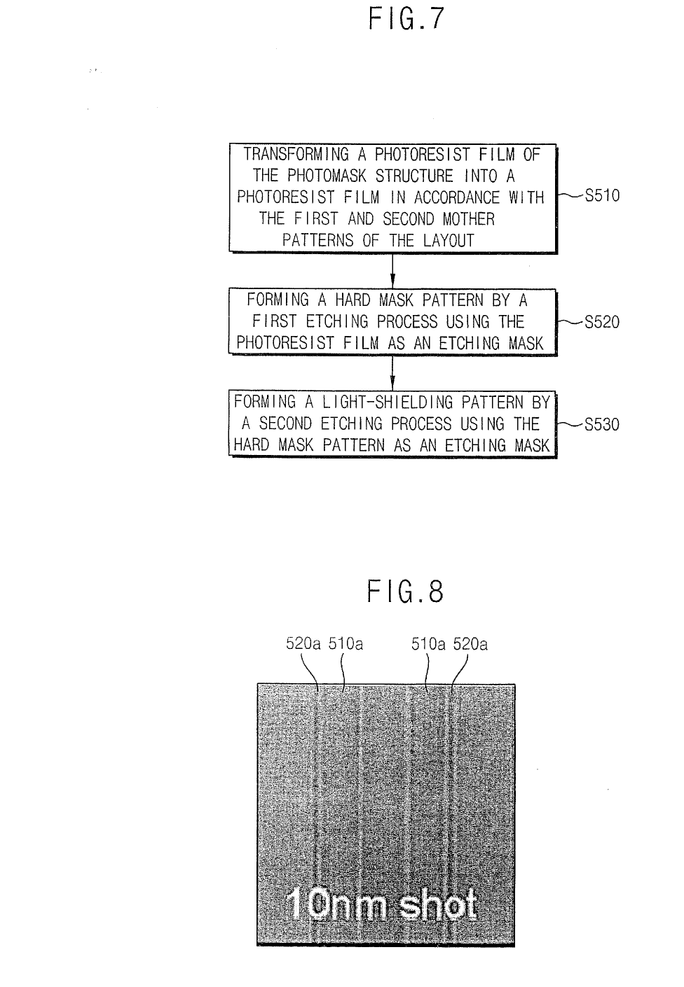

When the exposure process is completed on the photomask structure by every normal segment or reduced segment, a lithography process and an etching process are sequentially performed on the photomask structure to thereby form a photomask pattern on the transparent substrate (step S500). FIG. 7 is a flow chart showing a method of forming a photomask pattern in accordance with some embodiments of the present invention.

Referring to FIG. 7, the photomask structure is exposed to the electron beam and the photoresist film of the photomask structure is transformed into a photoresist pattern in accordance with the first and the second mother patterns 510 and 520 of the layout 500 (step S510). The first and the second exposure processes selectively change the molecular structure of the photoresist film, so that the molecular structures of a first portion of the photoresist film and a second portion of the photoresist film are different from each other. The first portion of the photoresist film corresponds to the first and the second mother patterns 510 and 520 of the layout 500, and the second portion of the photoresist film corresponds to the other portion of the layout 500 except for the first and the second mother patterns 510 and 520. The guide pattern 530 of the layout 500 functions as a mark for reducing the shot size of the electron beam, and is not transcribed onto the photomask structure during the exposure process. That is, the molecular structure of the photoresist film corresponding to the guide pattern 530 is not changed by the electron beam.

When the exposure process to the photoresist film of the photomask structure is completed, the photoresist film is then developed by a developing solution and is formed into the photoresist pattern in accordance with the first and the second mother patterns 510 and 520 of the layout 500. The difference of the molecular structure between an exposed portion and a non-exposed portion of the photoresist film leads to a solubility difference between the exposed portion and the non-exposed portion of the photoresist film in the developing solution including some chemicals. Accordingly, some portions of the photoresist film having a relatively greater solubility are removed from the photomask structure, and other portions of the photoresist film having a relatively smaller solubility remain in the photomask structure to thereby form the photoresist pattern on the photomask layer. In the present embodiment, the photoresist film includes the positive type photoresist materials, so that the exposed portion of the photoresist film is removed from the photomask structure to thereby form the photoresist pattern in accordance with the first and second mother patterns 510 and 520 of the layout 500. A thickness of the photoresist pattern is formed to be as small as possible in view of a thickness of the hard mask layer and the etching selectivity of the photoresist film with respect to the hard mask layer.

The hard mask layer is then partially removed from the hard mask structure by an etching process using the photoresist pattern as an etching mask, to thereby form a hard mask pattern on the light-shielding layer (step S520). Etching gas of the etching process may be varied in accordance with the materials of the hard mask layer. In some embodiments, when the hard mask layer comprises one of molybdenum (Mo), molybdenum silicon (MoSi) and molybdenum silicon oxynitride (MoSiON), some gases including halogen elements, such as fluorine (F), chlorine (Cl), bromine (Br) and iodine (I), may be used as the etching gas for the etching process against the hard mask layer. For example, when the hard mask layer comprises molybdenum silicon (MoSi), the etching gas may include one of CF₄, CHF₃, SF₆, Cl₂ and compositions thereof.

The light-shielding layer is partially removed by an etching process using the hard mask pattern as an etching mask, to thereby form a light-shielding pattern including the principal pattern and the supplementary pattern in accordance with the first mother pattern 510 and the second mother pattern 520 of the layout 500, respectively (step S530). For example, the etching process may include a plasma dry etching process using chlorine (Cl₂) gas and oxygen (O₂) gas as an etching gas. An inert gas, such as helium (He) and argon (Ar), may be supplementarily added to the etching gas of chlorine (Cl₂) gas and oxygen (O₂) gas in the above plasma etching process. In the above plasma etching process, a mixture ratio of the chlorine (Cl₂) gas and the oxygen (O₂) gas may be varied in accordance with an etching selectivity of the hard mask pattern with respect to the light-shielding layer in a range of about 2:1 to about 10:1.

The photomask pattern is then removed from the photomask structure to thereby form a photomask pattern including the principal pattern that is transcribed into a minute device pattern for a semiconductor device and the scattering bar that is a supplementary pattern for improving the transcription accuracy of the principal pattern onto a semiconductor substrate.

FIG. 8 is a scanning electron microscope (SEM) picture showing the photomask pattern that is formed by the method of forming the photomask pattern shown in FIG. 4.

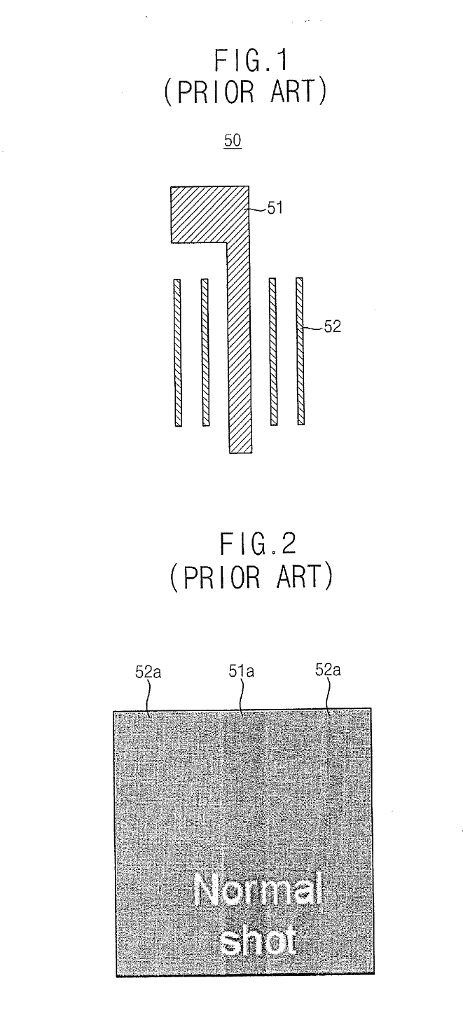

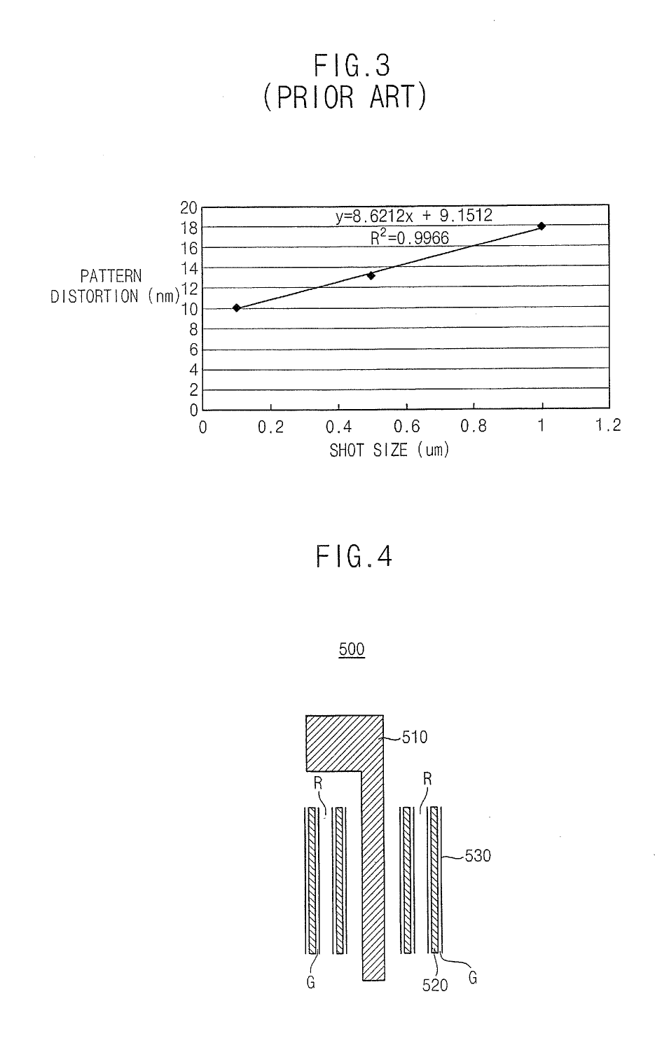

Referring to FIG. 8, the supplementary pattern 520a is accurately positioned along a boundary line of the principal pattern 510a in accordance with the second mother pattern 520 of the layout 500 without any pattern distortion. In contrast, as shown in FIG. 2, the second mother pattern of the conventional layout without the guide pattern is not accurately transcribed into the photomask pattern and the conventional supplementary pattern 52a is very different from the second mother pattern of the layout to thereby generate the pattern distortion. That is, the transcription accuracy of the layout may be sufficiently improved by the guide pattern thereof. Accordingly, the scattering bar may be sufficiently formed in the photomask pattern accurately in accordance with the guide pattern without any modifications to the exposure system despite the small line width and pitch thereof.

According to some embodiments of the present invention, an electron beam may be irradiated onto a minute region of a transparent substrate at a reduced shot size without any manual change between a normal region and the minute region of the transparent substrate, so that a photomask pattern is formed on the transparent substrate accurately in accordance with a layout despite a small line width and pitch thereof. Particularly, a scattering bar, which is a supplementary pattern for accurately transcribing a principal pattern of the photomask pattern into a minute device pattern without any pattern distortion, may be formed in the photomask pattern, to thereby sufficiently improve the resolution of the device pattern without any modifications to the exposure system.

Although some embodiments of the present invention have been described, it is understood that the present invention should not be limited to these embodiments but various changes and modifications can be made by one skilled in the art within the spirit and scope of the present invention as hereinafter claimed.

What is claimed is:

1. A layout for forming a photomask pattern, comprising:
a first mother pattern corresponding to a principal pattern of the photomask pattern, the principal pattern being transcribed onto a semiconductor substrate;
a second mother pattern corresponding to a supplementary pattern of the photomask pattern, the supplementary pattern being positioned between the principal patterns and configured to prevent transcription failures of the principal pattern without transcription onto the semiconductor substrate; and
a guide pattern that controls the shot size of illumination light for transcribing the first and the second mother patterns, respectively.

2. The layout of claim 1, wherein a plurality of the second mother patterns are positioned between a plurality of spaced apart first mother patterns along a longitudinal direction of the first mother patterns, each second mother pattern being spaced apart from a respective first mother pattern and an adjacent second mother pattern by a first distance.

3. The layout of claim 2, wherein the guide pattern is spaced apart from a boundary of the second mother pattern by a second distance and is aligned with the second mother pattern.

4. The layout of claim 3, wherein the second mother pattern has a width of about 100 nm to about 120 nm, and the first distance is in a range of about 200 nm to about 500 nm.

5. The layout of claim 3, wherein the second distance is in a range of about 20 nm to about 30 nm, and the guide pattern has a width smaller than the wavelength of illumination light for transcribing the first and second mother patterns, so that the guide pattern is not transcribed during an exposure process for forming the photomask pattern.

6. The layout of claim 1, wherein a plurality of the second mother patterns is positioned correspondingly to each of the corner portions of the first mother pattern, and the guide pattern is spaced apart from a boundary of the second mother pattern by a second distance and is aligned with the second mother pattern.

7. A method of forming a photomask pattern, comprising:
forming a layout for the photomask pattern, the layout including a first mother pattern corresponding to a principal pattern of the photomask pattern, a second mother pattern corresponding to a supplementary pattern of the photomask pattern, and a guide pattern that controls the shot size of illumination light for transcribing the first and the second mother patterns, respectively;
providing a photomask structure into a processing chamber of an exposure system, the photomask structure being formed into a photomask pattern by an exposure process in the exposure system;
inputting the layout into the exposure system;
exposing the photomask structure to the illumination light of the exposure system in accordance with the first and second mother patterns of the layout; and
forming the principal pattern and the supplementary pattern in the photomask structure in accordance with the first and second mother patterns of the layout to thereby form the photomask pattern, the principal pattern being transcribed onto a semiconductor substrate and the supplementary pattern being positioned between the principal patterns and configured to prevent transcription failures of the principal pattern without transcription onto the semiconductor substrate.

8. The method of claim 7, wherein forming the layout includes positioning the guide pattern along a boundary of the second mother pattern, and the guide pattern is spaced apart from the second mother pattern within an allowable detection error range of the exposure system with respect to the second mother pattern.

9. The method of claim 8, wherein forming the layout is performed by a computer graphic tool, and the layout is input into the exposure system as a graphic design system (GDS) computer image file.

10. The method of claim 9, wherein inputting the layout into the exposure system is performed simultaneously with a setting of recipes for the exposure process.

11. The method of claim 8, wherein the second mother pattern is spaced apart from the guide pattern by a distance of about 20 nm to about 30 nm.

12. The method of claim 7, wherein the exposure system detects the first and second mother patterns of the layout and irradiates the illumination light onto the photomask structure in accordance with the first and second mother patterns of the layout.

13. The method of claim 12, wherein the illumination light includes an electron beam.

14. The method of claim 7, wherein exposing the photomask structure includes:
detecting a non-pattern area of the layout in which the first mother pattern, the second mother pattern and the guide pattern are not positioned;
performing a first exposure process on the photomask structure by repeatedly irradiating the illumination light onto the photomask structure corresponding to the non-pattern area of the layout at a normal shot size, so that the photomask structure is exposed to the illumination light by every normal segment; and
performing a second exposure process on the photomask structure by repeatedly irradiating the illumination light onto the photomask structure corresponding to the non-pattern area of the layout near the guide pattern at a reduced shot size smaller than the normal size, so that the photomask structure is exposed to the illumination light by every reduced segment smaller than the normal segment in case that the guide pattern is detected.

15. The method of claim 14, wherein the layout includes a GDS computer image file, and detecting the non-pattern area of the layout includes scanning the layout by pixel.

16. The method of claim 14, wherein the normal segment includes a square having a length of about 200 nm to about 500 nm.

17. The method of claim 14, wherein the reduced segment includes a square having a length of about 20 nm to about 30 nm.

18. The method of claim 7, wherein the photomask structure includes a transparent substrate through which the illumination light passes, a light-shielding layer that is formed on the transparent substrate for selectively shielding the illumination light, a hard mask layer that is formed on the light-shielding layer and has an etching selectivity with respect to the light-shielding layer, and a photoresist film that is formed on the hard mask layer and of which the molecular structure is changed by the illumination light irradiated thereto.

19. The method of claim 18, wherein forming the principal pattern and the supplementary pattern includes:
transforming the photoresist film into a photoresist pattern in accordance with the first mother pattern and the second mother pattern of the layout by a photolithography process;
forming a hard mask pattern on the light-shielding layer by a first etching process using the photoresist pattern as an etching mask; and
forming a light-shielding pattern on the transparent substrate by a second etching process using the hard mask pattern as an etching mask, the light-shielding pattern including the principal pattern corresponding to the first mother pattern of the layout and the supplementary pattern corresponding to the second mother pattern of the layout.

20. The method of claim 18, wherein the first etching process includes a dry etching process using a gas comprising halogen elements as an etching gas, and the second etching process includes a plasma etching process using chlorine (Cl₂) gas and oxygen (O₂) gas as an etching gas.

21. The method of claim 18, wherein the transparent substrate includes a glass substrate, a fused silica substrate or a quartz substrate.

22. The method of claim 18, wherein the light-shielding layer includes a full light-shielding layer comprising any one material selected from the group consisting of aluminum (Al), tungsten (W) and chromium (Cr), or a half light-shielding layer comprising any one material selected from the group consisting of molybdenum (Mo), molybdenum silicon nitride (MoSiN) and molybdenum silicon oxynitride (MoSiON).
